(19) United States
(12) Patent Application Publication
(10) Pub. No.: US 2026/0106627 A1
(43) Pub. Date: Apr. 16, 2026

(54) DIGITAL TO ANALOG CONVERSION SYSTEM AND DIGITAL TO ANALOG CONVERSION METHOD

(71) Applicant: Realtek Semiconductor Corp., HsinChu (TW)

(72) Inventors: Kuei-Ying Lu, HsinChu (TW); Liang-Wei Huang, HsinChu (TW); Yu-Ting Chiu, HsinChu (TW); Yu-Chen Lee, HsinChu (TW)

(73) Assignee: Realtek Semiconductor Corp., HsinChu (TW)

(21) Appl. No.: 19/357,066

(22) Filed: Oct. 13, 2025

(30) Foreign Application Priority Data
Oct. 15, 2024 (TW) 113139116

(51) Int. Cl. H03M 1/70

(52) U.S. Cl. CPC H03M 1/70

(57) ABSTRACT

A digital to analog conversion method, comprising: converting a first N-bit control code to a first Y-bit control code according to a first control code conversion table stored in a storage device, wherein Y is greater than or equal to N; a DAC receiving the first Y-bit control code and outputting a first DAC output voltage among a plurality of DAC output voltages, wherein the number of the DAC output voltages is less than or equal to 2^{N}; and generating a second control code conversion table corresponding to variation of a state of the DAC, and updating the first control code conversion table in the storage device to the second control code conversion table.

### BACKGROUND OF THE INVENTION

### 1. Field of the Invention

The present invention relates to a digital to analog conversion system and a digital to analog conversion method, and particularly relates to a digital to analog conversion system and a digital to analog conversion method which can improve an DAC (DIGITAL TO ANALOG CONVERTER) output of a DAC.

### 2. Description of the Prior Art

Conventional DACs may cause errors in the DAC output voltage due to manufacturing processes or other reasons. For example, ideally, when the DAC receives a control code CD_a, it is expected to generate a DAC output voltage V_a. However, actually the DAC generates a DAC output voltage V_b when receiving the control code CD_a. This situation is called the DAC output voltage error. All control codes may have this problem. As a result, the circuit that operates based on the DAC output voltage may generate greater noise. This situation will be more obvious when the circuit area of the DAC is small.

### SUMMARY OF THE INVENTION

One objective of the present invention is to provide a digital to analog conversion system which can improve the DAC output voltage error.

Another objective of the present invention is to provide a digital to analog conversion method which can improve the DAC output voltage error.

One embodiment of the present invention discloses a digital to analog n system, comprising: a storage device, configured to store a first control code conversion table; a control code conversion circuit, configured to convert a first N-bit control code to a first Y-bit control code according to the first control code conversion table, wherein Y is greater than or equal to N; and a DAC, configured to receive the first Y-bit control code and configured to output a first DAC output voltage among a plurality of DAC output voltages, wherein the number of the DAC output voltages is less than or equal to 2^{N}; and a control circuit, configured to generate a second control code conversion table corresponding to variation of a state of the DAC, and configured to update the first control code conversion table in the storage device to the second control code conversion table.

Another embodiment of the present invention discloses a digital to analog conversion method, comprising: converting a first N-bit control code to a first Y-bit control code according to a first control code conversion table stored in a storage device, wherein Y is greater than or equal to N; a DAC receiving the first Y-bit control code and outputting a first DAC output voltage among a plurality of DAC output voltages, wherein the number of the DAC output voltages is less than or equal to 2^{N}; and generating a second control code conversion table corresponding to variation of a state of the DAC, and updating the first control code conversion table in the storage device to the second control code conversion table.

According to the foregoing embodiments, a control code conversion table can be used to convert the control code so that the DAC output voltage is close to the required output voltage, thereby improving the conventional DAC output voltage error problem. Further, the control code conversion table can be updated corresponding to the state variation of the DAC to ensure that the DAC output voltage error can always be maintained at a minimum value. In addition, the bias current of the DAC can be reduced as much as possible to reduce power consumption while ensuring that the noise level is acceptable.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating how to compensate a DAC output voltage error.

FIG. 2 is a block diagram illustrating digital to analog conversion systems according to different embodiments of the present invention.

FIG. 3 to FIG. 6 are schematic diagrams illustrating operations of digital to analog conversion systems according to different embodiments of the present invention.

FIG. 7 is a flow chart illustrating a flow chart of establishing a control code conversion table according to one embodiment of the present invention.

FIG. 8 is a block diagram illustrating a digital to analog conversion system which can update a control code conversion table, according to one embodiment of the present invention.

FIG. 9 is a schematic diagram illustrating that the monitoring circuit in FIG. 8 gradually changes the signal reception time, according to one embodiment of the present invention.

### DETAILED DESCRIPTION

Several embodiments are provided in following descriptions to explain the concept of the present invention. The term “first”, “second”, “third” in following descriptions are only for the purpose of distinguishing different one elements, and do not mean the sequence of the elements. For example, a first device and a second device only mean these devices can have the same structure but are different devices.

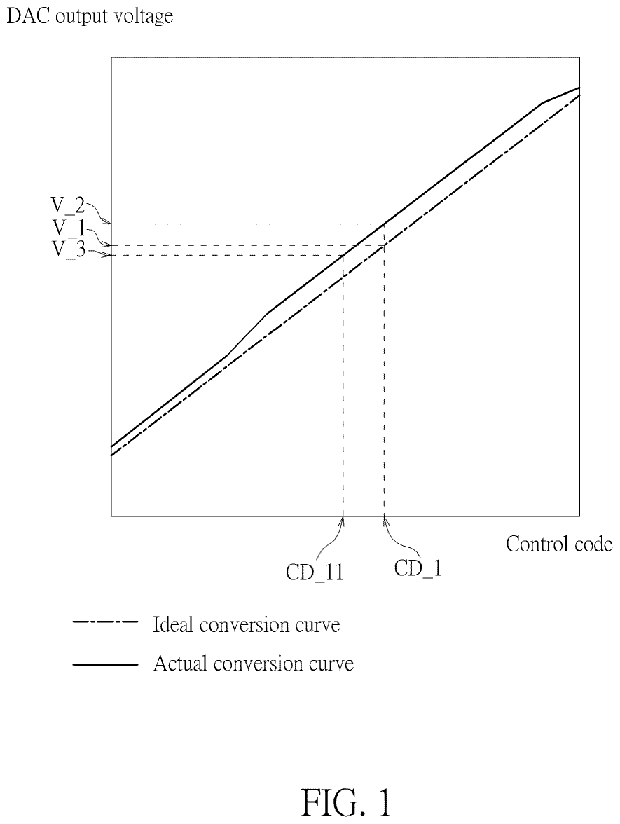

FIG. 1 is a schematic diagram illustrating how to compensate a DAC output voltage error. In FIG. 1, the DAC is expected to generate the DAC output voltage V_1 according to the ideal conversion curve when it receives the control code CD_1. However, in practical, the DAC generate the DAC output voltage V_2 according to the actual conversion curve when receiving the control code CD_1, so that the DAC output voltage corresponding to the control code CD_1 has a voltage difference of V_2-V_1. Such situation is the aforementioned “DAC output voltage error”. In order to compensate for the DAC output voltage error, the control code will be converted to another control code first, so that the DAC outputs the DAC output voltage closest to the original required output voltage according to the actual conversion curve, corresponding to the converted control code.

For example, in the embodiment of FIG. 1, the required output voltage is the DAC output voltage V_1, so before the DAC receives the control code, the control code CD_1 is converted to the control code CD_11, and then the DAC outputs DAC output voltage V_3 corresponding to control code CD_11 according to the actual conversion curve. The DAC output voltage V_3 is the DAC output voltage closest to the required output voltage V_1 among all the DAC output voltages generated by all control codes according to the actual conversion curve. All control codes can be converted following such rules.

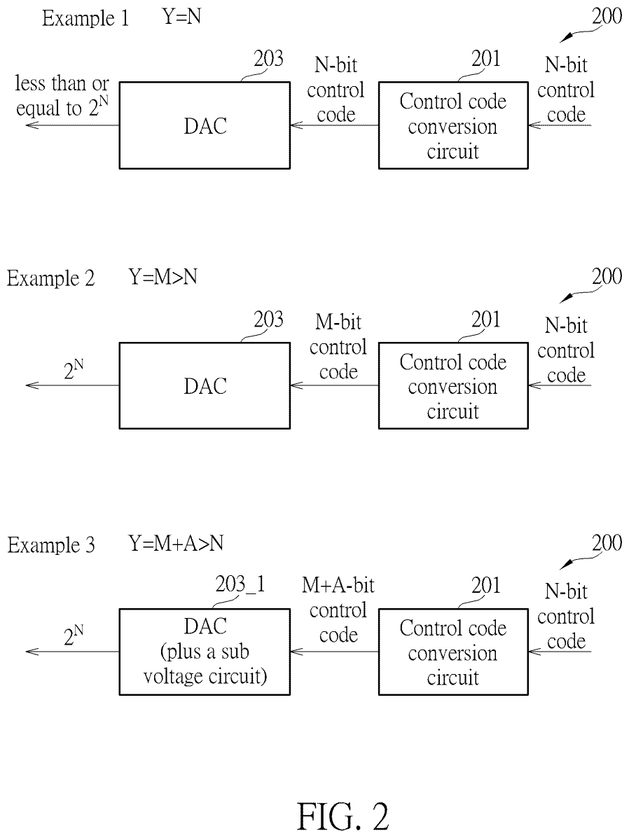

Following the concept of FIG. 1, the present invention provides a digital to analog conversion system that can convert control codes. FIG. 2 is a block diagram illustrating digital to analog conversion systems according to different embodiments of the present invention. In Example 1, Example 2 and Example 3 of FIG. 2, the digital to analog conversion system 200 comprises a control code conversion circuit 201 and a DAC 203. The control code conversion circuit 201 may be implemented by hardware (for example, a circuit or a device) or software (for example, executed by a processing circuit). In Example 1, the control code conversion circuit 201 converts the N-bit control code to an N-bit control code according to a control code conversion table, so the DAC 203 outputs one of a plurality of DAC output voltages according to the received control code. The number of output voltages of these plural DACs is less than or equal to 2^{N}. In Example 2, the control code conversion circuit 201 converts the N-bit control code to an M-bit control code according to the control code conversion table. M is greater than N, so the DAC 203 has 2^{M} candidate output voltages. The DAC 203 will select DAC output voltages that are closest to the 2^{N} original required output voltage from the 2^{M} candidate output voltages. Therefore, the DAC 203 outputs one of the 2^{N} DAC output voltages according to the received control code. Please also note that in Example 2, the 2^{M} candidate output voltages will only appear when the control code conversion table is generated. During normal operation, the DAC 203 outputs one of the last selected 2^{N} DAC output voltages.

In Example 3, the control code conversion circuit 201 converts the N-bit control code to an M+A-bit control code according to the control code conversion table. In this case, the M-bit control code is a main control code and the A-bit sub control code is a sub control code, and A is a positive integer. The main control code is used to generate the main voltage and the sub control code is used to generate the sub voltage. DAC 203_1 still have 2^{M} candidate output voltages, but the 2^{M} candidate output voltages are respectively formed by the main voltage plus the sub voltage. In Example 2, the 2^{M} candidate output voltages are only formed by the main voltage respectively. In Example 3, DAC 203_1 selects the main voltage based on 2^{M} candidate output voltages, and then generates the sub voltage based on the A-bit sub control code, and then generate 2^{N} DAC output voltages accordingly. Afterwards, the DAC 203 outputs one of the 2^{N} DAC output voltages according to the control code. Details about each example are described below.

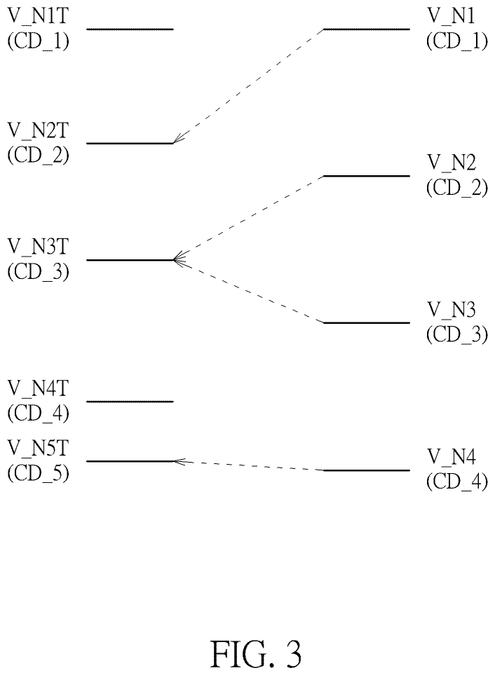

FIG. 3 to FIG. 6 are schematic diagrams illustrating operations of digital to analog conversion systems according to different embodiments of the present invention. In the embodiments of FIGS. 3 to 6, only a few required output voltages and DAC output voltages are illustrated. However, the number of required output voltages and DAC output voltages is not limited to the numbers in FIGS. 3 to 6. FIG. 3 corresponds to Example 1 in FIG. 2. In the embodiment of FIG. 3, the DAC output voltages V_N1, V_N2, and V_N3 are respectively the required output voltages corresponding to the N-bit control codes CD_1, CD_2, and CD_3 received by the control code conversion circuit 101. The DAC output voltages V_N1T, V_N2T, and V_N3T are the DAC output voltages generated by DAC 103 corresponding to the N-bit control codes CD_1, CD_2, and CD_3 and based on the actual conversion curve in FIG. 1.

In the embodiment of FIG. 3, the conversion relationship of the N-bit control code is determined based on the relationship between the required output voltage and the closest DAC output voltage. For example, the required output voltage V_N1 is closest to the DAC output voltage V_N2T, so the control code conversion circuit 101 converts the received N-bit control code CD_1 to the N-bit control code CD_2 corresponding to the DAC output voltage V_N2T. For another example, the required output voltage V_N4 is closest to the DAC output voltage V_N5T, so the control code conversion circuit 101 converts the received N-bit control code CD_4 to the N-bit control code CD 5 corresponding to the DAC output voltage V_N5T. Please note, in FIG. 3, different required output voltages can correspond to the same DAC output voltage. For example, the voltage difference between the DAC output voltage V_N3T and the required output voltages V_N2 and V_N3 is the same, but the voltage difference between the DAC output voltage V_N4T and the required voltage V_N3 is large. Therefore, in this case, the required output voltages V_N2 and V_N3 will both correspond to the DAC output voltage V_N3T. That is, the control code CD_2 corresponding to the required output voltage V_N2 and the control code CD_3 corresponding to the required output voltage V_N3 will both be converted to the control code CD_3 corresponding to the DAC output voltage V_N3T.

In addition, in the embodiment of FIG. 3, some DAC output voltages are greatly different from the required voltages, so they will not correspond to any converted control code, and will not be output by the DAC 103. For example, the DAC output voltages V_N1T and V_N4T do not correspond to any converted control code, and therefore are not output by the DAC 103. According to the above content, since the DAC output voltage in FIG. 3 does not necessarily have a one to corresponding relationship with the required output voltage. Also, some DAC output voltages will not be used, thus the 2^{N} N-bit control codes received by the control code conversion circuit 101 may make the total number of DAC output voltages be equal to or less than 2^{N}. In the aforementioned embodiment of FIG. 3, all 2^{N} voltages generated by the DAC 201 receiving the converted N-bit control code can also be regarded as candidate output voltages, and the final DAC output is the DAC output voltage.

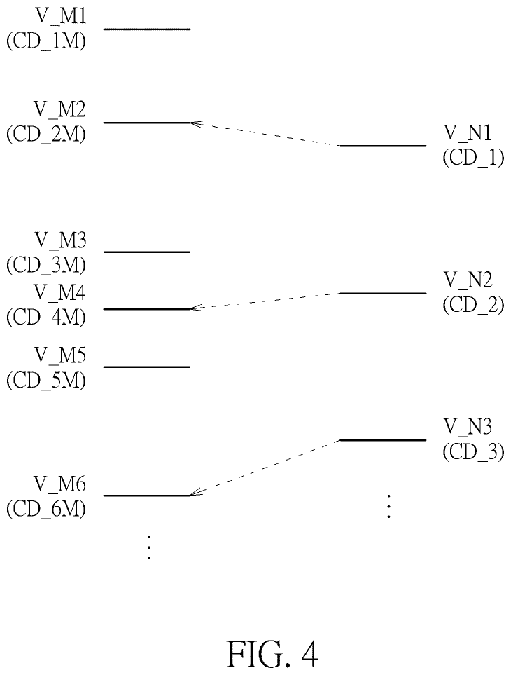

FIG. 4 corresponds to Example 2 in FIG. 2, that is, the control code conversion circuit 201 will convert the N-bit control code to an M-bit control code. In FIG. 4, the DAC output voltages V_N1, V_N2, and V_N3 are the required output voltages corresponding to the N-bit control codes CD_1, CD_2, and CD_3. The DAC output voltages V_M1, V_M2, V_M3, V_M4, V_M5, and V_M6 are the candidate output voltages generated by the DAC 103 corresponding to the M-bit control codes CD_1M, CD_2M, CD_3M, CD_4M, CD_5M, and CD_6M according to the actual conversion curve in FIG. 1. The DAC 103 will generate 2^{M} candidate output voltages based on all M-bit control codes. Since M is greater than N, the number 2^{M} of candidate output voltages will also be greater than the number 2^{N} of required output voltages.

Next, the 2^{N} candidate output voltages respectively closest to the required output voltage will be selected from the 2^{M} candidate output voltages as the DAC output voltages, and the control code will be converted accordingly. For example, the candidate output voltage closest to the required output voltage V_N1 is V_M2, so the candidate output voltage V_M2 will be used as the DAC output voltage. Further, the control code conversion circuit 201 will convert the control code CD_1 corresponding to the required output voltage V_N1 to the control code CD_2M corresponding to the candidate output voltage V_M2. For another example, the candidate output voltage closest to the required output voltage V_N2 is V_M4, so the candidate output voltage V_M4 will be used as the DAC output voltage. The control code conversion circuit 201 will convert the control code CD_2 corresponding to the required output voltage V_N2 to the control code CD_4M corresponding to the candidate output voltage V_M4. In the embodiment of FIG. 4, since the number 2^{M} of candidate output voltages will be greater than the number 2^{N} of required output voltages, a closer candidate output voltage can be found for each required output voltage, so the required output voltage and the DAC output voltage can be a one to one corresponding relationship. In this case, the number of DAC output voltages that the DAC 103 can finally output and the number of required output voltages can both be 2^{N}.

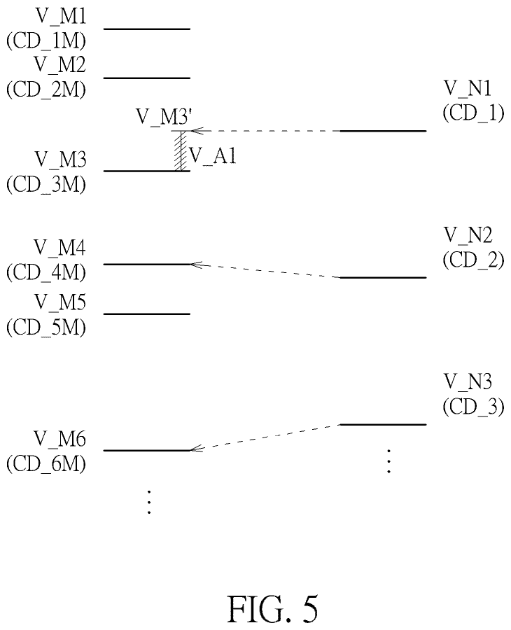

FIG. 5 corresponds to Example 3 in FIG. 2. The control code conversion circuit 201 will convert the N-bit control code to an M+A-bit control code, that is, the M-bit main control code and the A-bit sub control code. A is a positive integer, which is 1 in the embodiment of FIG. 5. Also, the DAC 203_1 has one more sub voltage circuit than DAC 203. In one embodiment, the DAC output voltage of the DAC 203 is generated based on the current provided by the current source. Therefore, the sub voltage circuit can also be a current source, and its circuit area determines the maximum sub voltage that can be generated. The way DAC 203_1 generates the main voltage based on the M-bit main control code is the same as the way it generates the candidate output voltage based on the M-bit control code in FIG. 4. For example, in FIG. 5, the DAC 203_1 can generate the main voltages V_M1 and V_M2 according to the M-bit main control codes CD_1M and CD_2M respectively. The A-bit sub control code is used to determine whether the sub voltage circuit provides a sub voltage. Through the combination of main voltage and sub voltage, DAC 203_1 can make the required output voltage correspond to a closer DAC output voltage.

For example, in the embodiment of FIG. 5, the required output voltage V_N1 corresponding to the control code CD_1 falls between in a middle of the candidate output voltages V_M2 and V_M3, so the required output voltage V_N1 has a greater output voltage error no matter the control code CD_1 is converted to the control code CD_1M or CD_2M. In this case, the sub control code can be used to control the sub voltage circuit to provide a sub voltage, so that the required output voltage V_N1 corresponds to the DAC output voltage V_M3′ which is formed by the candidate output voltage V_M3 plus the sub voltage V_A1. By this way, the output voltage error of the required output voltage V_N1 can be reduced. In this case, the control code conversion circuit 201 will convert the control code CD_1 to a control code (CD_3M+A1). The main control code CD_3M determines the value of the main voltage to be V_M3, and the sub control code A1 represents that the sub voltage circuit will provide a sub voltage. In addition, in the embodiment of FIG. 5, other control codes are also converted to M+A bit control codes. For example, the control code CD_3 will be converted to a control code (CD_6M+A2). The main control code CD_6M determines the value of the main voltage to be V_M6, and the sub control code A2 represents that the sub voltage circuit will not provide the sub voltage.

In the embodiment of FIG. 5, if the DAC 203_1 receives M-bit main control codes with M different bit values, it will generate 2^{M} main voltages accordingly. There will be a voltage difference between adjacent main voltages, that is, between the closest main voltages. For example, there will be a voltage difference between the main voltages V_M2 and V_M3, and there will be a voltage difference between the main voltages V_M3 and V_M4. In the embodiment of FIG. 5, the sub voltage will be less than this voltage difference. Please also note that there may be different voltage differences between different adjacent mains voltages. In this situation, the sub voltage may be less than the smallest voltage difference among all different voltage differences.

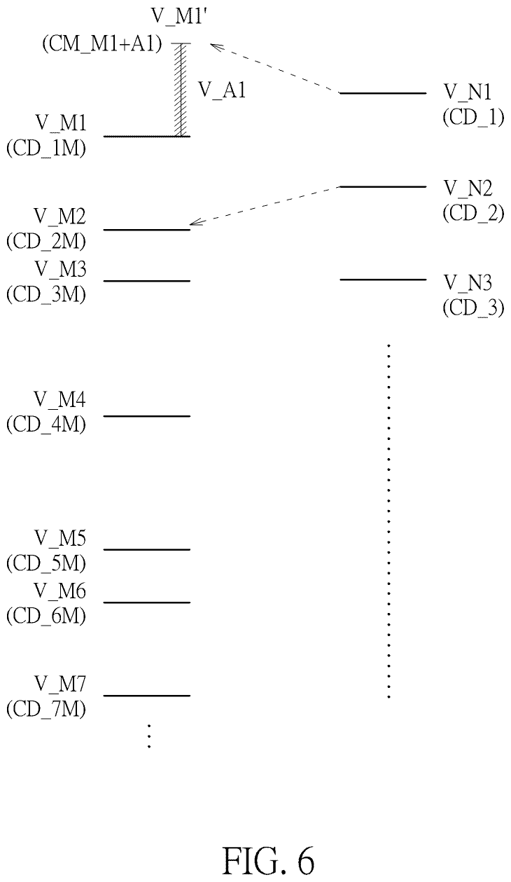

In the embodiment of FIG. 5, the sub voltage is used to allow the required output voltage to more accurately correspond to the DAC output voltage. In this case, the sub voltage can be designed to be less than the voltage difference. However, in another embodiment, the sub voltage may be used to increase the swing of the DAC output voltage. As shown in FIG. 6, the main voltage V_M1 is the largest voltage among all main voltages, but it is still less than the required output voltage V_N1. In this case, a sub voltage V_A1 can be added to the main voltage V_M1 to generate the DAC output voltage V_M1′. By this way, the required output voltage V_1N can be made to correspond to the DAC output voltage V_M1′, that is, the control code CD_1 is converted to an M+A bit control code (CD_M1+A1). The main control code CD_M1 determines the main voltage V_M1, and the sub control code A1 represents that the sub voltage circuit will generate the sub voltage V_A1. In the embodiment of FIG. 6, the sub voltage can be selected to have a greater value, for example, it can be greater than the voltage difference of the aforementioned main voltage. In addition, in the embodiment of FIG. 6, other control codes are also converted to M+A bit control codes. For example, the control code CD_2 will be converted to a control code (CD_M2+A2). The main control code CD_2M determines the value of the main voltage to be V_M2, and the sub control code A2 represents that the sub voltage circuit will not provide the sub voltage.

According to the aforementioned embodiments, the digital to analog conversion system in FIG. 2 can be briefly described as: a control code conversion circuit, configured to convert a first N-bit control code to a first Y-bit control code according to a control code conversion table, wherein Y is greater than or equal to N; and a DAC, configured to receive the first Y-bit control code and configured to output a first DAC output voltage among a plurality of DAC output voltages.

In Example 1, Y=N. In the corresponding embodiment of FIG. 3, the control code conversion circuit 101 converts the N-bit control code CD_2 (the first N-bit control code) to the N-bit control code CD_3 (the first Y-bit control code). The DAC 203 outputs the corresponding DAC output voltage V_N3T (the first DAC output voltage) according to the control code CD_3. In Example 2, Y=M. In the corresponding embodiment of FIG. 4, the control code conversion circuit 101 converts the N-bit control code CD_1 (the first N-bit control code) to the M-bit control code CD_2M (the first Y-bit control code). The DAC 203 outputs the corresponding DAC output voltage V_M2 (the first DAC output voltage) according to the control code CD_2M. In Example 3, Y=M+A. In the corresponding embodiment of FIG. 5, the control code conversion circuit 101 converts the N-bit control code CD_1 (the first N-bit control code) to the M+A-bit control code CD_3M+A1 (the first Y-bit control code). The DAC 203 outputs the corresponding DAC output voltage V_M3′ (the first DAC output voltage) according to the control code CD_3M+A1.

In one embodiment, if the DAC receives the unconverted first N-bit control code, it will generate a second DAC output voltage that is different from the first DAC output voltage. Taking FIG. 4 as an example, if the DAC 203 receives the unconverted control code CD_1 (the first N-bit control code) instead of the converted control code CD_2M, it will generate a DAC output voltage (second DAC output voltage) DAC different from the DAC output voltage V_M2 (the first DAC output voltage). Therefore, if the control code CD_1 is directly received by the DAC 203 without conversion, the required output voltage V_N1 corresponding to the control code CD_1 will have a large output voltage error.

The DAC may also have similar actions when accepting other control codes. In one embodiment, the control code conversion circuit 201 converts a second N-bit control code to a second Y-bit control code according to the control code conversion table. For example, in the embodiment of FIG. 4, the N-bit control code CD_2 is converted to an M-bit control code CD_4M. After the DAC receives the second Y-bit control code, it will output a third DAC output voltage. For example, after the DAC receives the control code CD_4M, it will output the DAC output voltage V_M4. If the DAC receives the second N-bit control code, a fourth DAC output voltage different from the third DAC output voltage will be generated. For example, if the DAC receives the unconverted control code CD_2, it will generate a fourth DAC output voltage that is different from the DAC output voltage V_M4.

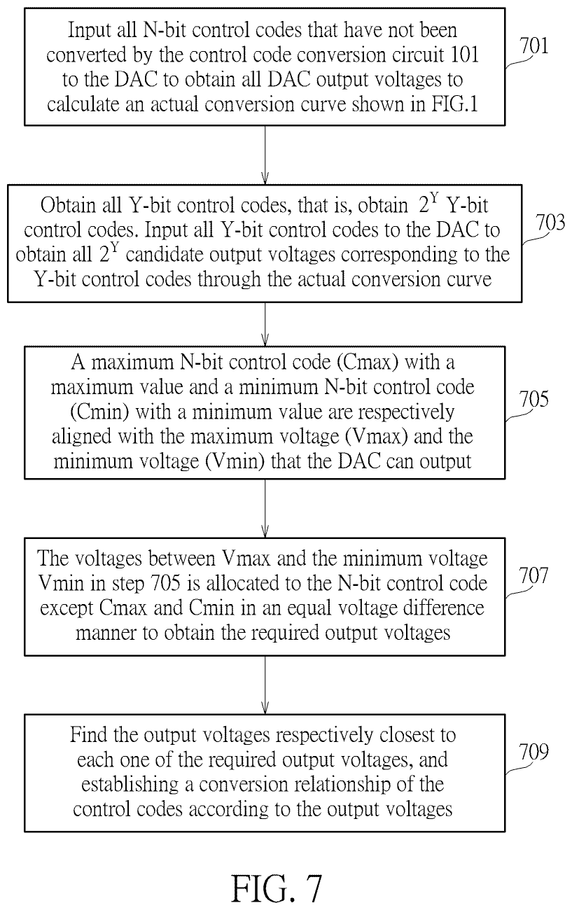

As mentioned above, the control code conversion circuit 101 converts the control code according to a control code conversion table. This control code conversion table can be created in various ways. FIG. 7 is a flow chart illustrating a flow chart of establishing a control code conversion table according to one embodiment of the present invention.

, which comprises the following steps:

### Step 701

Input all N-bit control codes that have not been converted by the control code conversion circuit 101 to the DAC to obtain all DAC output voltages to calculate an actual conversion curve shown in FIG. 1.

### Step 703

Obtain all Y-bit control codes, that is, obtain 2^{Y} Y-bit control codes. Input all Y-bit control codes to the DAC to obtain all 2^{Y} candidate output voltages corresponding to the Y-bit control codes through the actual conversion curve.

That is, the actual conversion curve is used to obtain the DAC output voltages corresponding to the Y-bit control code. As mentioned before, Y can be N, M or M+A. The Y bit control code can be a predetermined group of codes, or a code entered during DAC calibration, or a group of continuous codes determined by the software.

### Step 705

A maximum N-bit control code (Cmax) with a maximum value and a minimum N-bit control code (Cmin) with a minimum value are respectively aligned with the maximum voltage (Vmax) and the minimum voltage (Vmin) that the DAC can output.

### Step 707

The voltages between Vmax and the minimum voltage Vmin in step 705 is allocated to the N-bit control code except Cmax and Cmin in an equal voltage difference manner to obtain the required output voltages.

In detail, the total number of the N-bit control codes except Cmax and Cmin is 2^{N}−2. There will be a control code interval between two closest N-bit control codes, and there will be 2^{N}−1 control code interval between the 2^{N} N-bit control codes. Therefore, the voltage difference between the DAC output voltages corresponding to the two closest N-bit control codes will be

$$\frac{V max - V min}{{2}^{N} - I} .$$

For example, if N=3, there are a total of 8 N-bit control codes, and there will be 6 N-bit control codes except Cmax and Cmin. The two closest N-bit control codes will have one control code interval, and the eight N-bit control codes will have 7 control code intervals. Therefore, the voltage difference between the DAC output voltages corresponding to the two closest N-bit control codes will be

$$\frac{V max - V min}{7} .$$

According to such rules, all required output voltages can be obtained.

### Step 709

Find at least one output voltage among the candidate output voltages, wherein the output voltage is respectively closest to each one of the required output voltages, and establishing a conversion relationship of the control codes according to the output voltages.

The rules of the conversion relationship of the control codes have been described in detail in the aforementioned embodiments of FIGS. 2 to 6, so are omitted for brevity here.

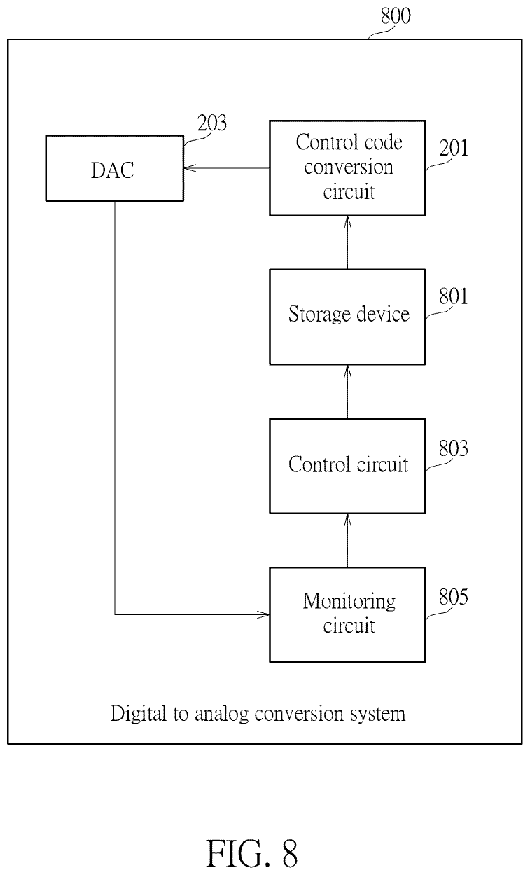

The actual conversion curve in the aforementioned FIG. 2 may change due to the state variation of the DAC. In this case, the aforementioned control code conversion table can be dynamically updated to ensure that the control code conversion table corresponds to the latest actual conversion curve. FIG. 8 is a block diagram illustrating a digital to analog conversion system which can update a control code conversion table, according to one embodiment of the present invention. As shown in FIG. 8, the digital to analog conversion system 800 further comprises a storage device 801 and a control circuit 803 in addition to the control code conversion circuit 201 and the DAC 203 described in FIG. 2. Please also note that the DAC comprised in the digital to analog conversion system 800 can also be the DAC 203_1 in FIG. 2, which is a DAC that comprises a sub voltage circuit. The storage device 801 is configured to store a first control code conversion table, the content of which can be the same as the control code conversion table in the previous embodiments. The control circuit 803 generates a second control code conversion table corresponding to variation of the state of the DAC 203, and updates the first control code conversion table in the storage device 801 to the second control code conversion table. Both the first control code conversion table and the second control code conversion table can be generated through the steps shown in FIG. 7, but are not limited thereto.

In one embodiment, the state of the DAC comprises at least one of the following: a time for the DAC to transmit a signal, a temperature of the DAC, an operating voltage of the DAC, a bias current of the DAC, and a usage time of the DAC. Changes of a time for the DAC to transmit a signal may represent changes in the internal circuit conditions of the DAC, which may affect the value of the DAC output voltage corresponding to the same control code (that is, changing the actual conversion curve in FIG. 2), so the control code conversion table can be updated based on changes of a time for the DAC to transmit a signal. The temperature of the DAC may affect the operation of the internal circuit of the DAC and thereby affect the value of the DAC output voltage corresponding to the same control code. Therefore, the control code conversion table can be updated corresponding to the change in the temperature of the DAC. The operating voltage and the bias current of the DAC may be affected by the drift of the voltage source or current source, which may affect the value of the DAC output voltage corresponding to the same control code, so the control code conversion table can be updated corresponding to changes in the operating voltage or bias current of the DAC. After the DAC has been used for a long time, the circuit may age and affect the value of the DAC output voltage corresponding to the same control code. Therefore, the control code conversion table can be updated according to the usage time of the DAC.

The state of the aforementioned DAC can be monitored or obtained through various methods. In one embodiment, the digital to analog conversion system 800 may further comprise a monitoring circuit 805 for monitoring the time of the output signal of the DAC 203. Specifically, the monitoring circuit 805 receives an output of the DAC 203 and triggers an update of the control code conversion table based on the state of the received signal. The monitoring circuit 805 and the control circuit 803 can be integrated into the same circuit. In one embodiment, the monitoring circuit 805 is an ADC (Analog to Digital Converter). However, please note that the digital to analog conversion system 800 is not limited to comprising the monitoring circuit 805. It can use different circuits or devices to trigger the update of the control code conversion table corresponding to different types of DAC states. In one embodiment, the monitoring circuit 805 receives the output of the DAC 203 in a reception time period. The DAC 203 changes the time it transmits the signal in a time interval from a time of starting up to a time of reaching a stable state. Therefore, the signal reception time of the monitoring circuit 805 is also affected by the signal transmission time of the DAC 203. In this case, the monitoring circuit gradually changes a starting point of the reception time period. When a change amount of the starting point is greater than a threshold value, the control circuit 803 is triggered by the monitoring circuit 805 to generate the second control code conversion table, and updates the first control code conversion table in the storage device 801 to the second control code Conversion table. For convenience of explanation, such an action will be simply referred to as “the control circuit 803 is triggered by the monitoring circuit 805” in following descriptions.

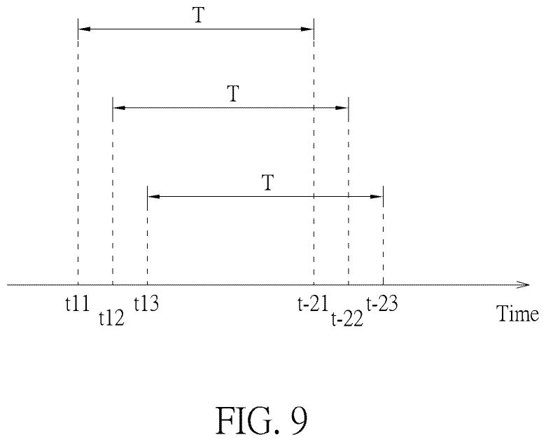

FIG. 9 is a schematic diagram illustrating that the monitoring circuit in FIG. 8 gradually changes the signal reception time, according to one embodiment of the present invention. As shown in FIG. 9, the monitoring circuit 805 initially receives the signal output by the DAC 203 at time t_11 (e.g., samples the output), and then receives the signal output by the DAC 203 again at time t_21. In this case, the reception time period is T. As mentioned above, the monitoring circuit 805 gradually changes the starting point of the reception time period T corresponding to the time when the DAC 203 outputs the signal. Therefore, in the next round of signal reception, the starting point of the reception time period T will be changed to time t_12. Since the reception time period T remains the same, the next signal reception time is t_22, and the interval between time t_12 and t_22 is still the reception time period T. Following the same rule, in the next round of signal receiving action, the time of receiving the output of DAC 203 will be changed to time t_13 and t_23. When a change amount of the starting point is greater than a threshold value, it means that the state variation of the DAC 203 also exceeds a predetermined degree, so the control circuit 803 is triggered by the monitoring circuit 805. For example, if the starting point gradually changes from time t_11 to t_13, and the difference between time t_11 and time t_13 is greater than T/K, the control circuit 803 is triggered by the monitoring circuit 805. K may be a natural number and depends on a variation ratio between a variation of the DAC output voltage error of DAC 203 and the state variation. If the variation ratio is small, K can be set to a smaller value, that is, the tolerance for state variation of the DAC 203 is larger. On the contrary, if the variation ratio is large, K can be set to a larger value, that is, the tolerance to the state change of the DAC 203 is smaller.

The aforementioned changes in the actual conversion curve will cause the DAC 203 to generate noise. In addition, the magnitude of the bias current of the DAC 203 will also affect the noise of the DAC 203. The larger the bias current, the lower the noise of DAC 203, but there will be greater power consumption. On the contrary, the smaller the bias current, the higher the noise of DAC 203, but can have smaller power consumption. Therefore, the present invention also proposes a method for setting the size of the bias current. In this embodiment, the DAC 203 operates based on a bias current, and the control circuit 803 further adjusts the bias current based on a signal-to-noise ratio (SNR) of the DAC 203.

In one embodiment, the bias current has a plurality of current levels, and the control circuit 803 adjusts the bias current according to the SNR through the following steps: If the SNR is greater than an SNR threshold (that is, the noise is low), then continue reducing the current level until the SNR is greater than the SNR threshold value but closest to the SNR threshold value, or is less than the SNR threshold value but closest to the SNR threshold value. On the contrary, if the SNR is less than the SNR threshold value (that is, the noise is high), the current level is continuously increased until the SNR is greater than the SNR threshold value, or is less than the SNR threshold value but closest to the SNR threshold value. In other words, such example reduces the bias current of the DAC as much as possible while ensuring that the noise level is acceptable.

For example, if the bias current has 11 current levels, and the current levels are I1, I2 . . . I11 from small to large. Then one of them will be selected as the initial current level. In one example, the middle current level I6 is selected as the initial current level. Then, it will confirm whether the SNR of the DAC is greater than the SNR threshold value. If the SNR is greater than the SNR threshold value, the current level will continue to be reduced until it is greater than the SNR threshold value but closest to the SNR threshold value, or less than the SNR threshold value but closest to the SNR threshold value. For example, the current level is reduced to the I5 first, and then is reduced to the current level I4 if the SNR is still greater than the SNR threshold. This step will be repeated until the current level is reduced to the current level I2, that is, until the SNR is greater than the SNR threshold value but closest to the SNR threshold value, or is less than the SNR threshold value but closest to the SNR threshold value.

On the contrary, if the SNR is less than the SNR threshold value, the current level is continuously increased until the SNR is greater than the SNR threshold value, or is less than the SNR threshold value but closest to the SNR threshold value. For example, the current level is increased to I7 first, and then is increased the current level to I8 if the SNR is still less than the SNR threshold. This step will be repeated until the current level is increased to I9, that is, until the SNR is greater than the SNR threshold value or less than the SNR threshold value but closest to the SNR threshold value. The step of adjusting the SNR may be performed in conjunction with the aforementioned state of the DAC 203. In detail, when confirming the SNR, the SNR of the DAC 203 in all states is confirmed. When the SNR in all states is greater than the SNR threshold value, the DAC 203 will determine that the SNR is greater than the SNR threshold value and adjust the current level accordingly. On the contrary, as long as the SNR in a state is less than the SNR threshold value, the DAC 203 will determine that the SNR is less than the SNR threshold value and adjust the current level accordingly.

According to the foregoing embodiments, a digital to analog conversion method can be obtained, which corresponds to the embodiments of FIGS. 8 and 9. The digital to analog conversion method comprises the following steps: converting a first N-bit control code to a first Y-bit control code according to a first control code conversion table stored in a storage device (such as the storage device 801), wherein Y is greater than or equal to N; and a DAC (such as DAC 203 or 203_1) receiving the first Y-bit control code and outputting a first DAC output voltage among a plurality of DAC output voltages, wherein the number of the DAC output voltages is less than or equal to 2^{N}; and generating a second control code conversion table corresponding to variation of a state of the DAC, and updating the first control code conversion table in the storage device to the second control code conversion table.

Other steps can be acquired based on the above embodiments, thus are omitted for brevity here.

According to the foregoing embodiments, a control code conversion table can be used to convert the control code so that the DAC output voltage is close to the required output voltage, thereby improving the conventional DAC output voltage error problem. Further, the control code conversion table can be updated corresponding to the state variation of the DAC to ensure that the DAC output voltage error can always be maintained at a minimum value. In addition, the bias current of the DAC can be reduced as much as possible to reduce power consumption while ensuring that the noise level is acceptable.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A digital to analog conversion system, comprising:
a storage device, configured to store a first control code conversion table;
a control code conversion circuit, configured to convert a first N-bit control code to a first Y-bit control code according to the first control code conversion table, wherein Y is greater than or equal to N;
a DAC, configured to receive the first Y-bit control code and configured to output a first DAC output voltage among a plurality of DAC output voltages, wherein the number of the DAC output voltages is less than or equal to 2^{N}; and
a control circuit, configured to generate a second control code conversion table corresponding to variation of a state of the DAC, and configured to update the first control code conversion table in the storage device to the second control code conversion table.

2. The digital to analog conversion system of claim 1, wherein the state comprises at least one of: a time for the DAC to transmit a signal, a temperature of the DAC, an operating voltage of the DAC, a bias current of the DAC, and a usage time of the DAC.

3. The digital to analog conversion system of claim 1, further comprising:
a monitoring circuit, configured to receive an output of the DAC;
wherein the monitoring circuit receives the output of the DAC in a reception time period, and the monitoring circuit gradually changes a starting point of the reception time period;
wherein when a change amount of the starting point is greater than a threshold value, the monitoring circuit triggers the control circuit to generate the second control code conversion table and to update the first control code conversion table in the storage device to the second control code conversion table.

4. The digital to analog conversion system of claim 1, wherein the monitoring circuit is an ADC.

5. The digital to analog conversion system of claim 1, wherein the DAC operates based on a bias current, and the control circuit further adjusts the bias current based on an SNR (Signal to Noise Ratio) of the DAC.

6. The digital to analog conversion system of claim 5, wherein the bias current has a plurality of current levels, and the control circuit adjusts the bias current according to the SNR through following steps:
if the SNR is greater than an SNR threshold, continuing reducing the current level until the SNR being greater than the SNR threshold but closest to the SNR threshold, or less than the SNR threshold but closest to the SNR threshold;
if the SNR is less than the SNR threshold, continuing increasing the current level until the SNR being greater than the SNR threshold, or less than the SNR threshold but closest to the SNR threshold.

7. The digital to analog conversion system of claim 1, if the DAC receives the first N-bit control code, the DAC generates a second DAC output voltage different from the first DAC output voltage.

8. The digital to analog conversion system of claim 1, wherein the first control code conversion table and the second control code conversion table are generated by following steps:
inputting a plurality of N-bit control codes to the DAC to calculate an actual conversion curve;
obtaining 2^{Y} Y-bit control codes, and obtaining all candidate output voltages corresponding to the 2^{Y} Y-bit control codes through the actual conversion curve;
aligning a maximum one and a minimum one among the N-bit control codes to a maximum voltage and a minimum voltage that the DAC can output respectively;
allocating voltages between the maximum voltage and the minimum voltage to the N-bit control codes except the maximum N-bit control code and the minimum N-bit control code in an equal voltage difference manner, to obtain a plurality of required output voltages;
finding at least one output voltage among the candidate output voltages, wherein the output voltage is respectively closest to each one of the required output voltages, and establishing a conversion relationship of the control codes according to the output voltage.

9. A digital to analog conversion method, comprising:
converting a first N-bit control code to a first Y-bit control code according to a first control code conversion table stored in a storage device, wherein Y is greater than or equal to N;
a DAC receiving the first Y-bit control code and outputting a first DAC output voltage among a plurality of DAC output voltages, wherein the number of the DAC output voltages is less than or equal to 2^{N}; and
generating a second control code conversion table corresponding to variation of a state of the DAC, and updating the first control code conversion table in the storage device to the second control code conversion table.

10. The digital to analog conversion method of claim 9, wherein the state comprises at least one of: a time for the DAC to transmit a signal, a temperature of the DAC, an operating voltage of the DAC, a bias current of the DAC, and a usage time of the DAC.

11. The digital to analog conversion method of claim 9, further comprising:
a monitoring circuit receiving an output of the DAC;
wherein the monitoring circuit receives the output of the DAC in a reception time period, and the monitoring circuit gradually changes a starting point of the reception time period;
wherein when a change amount of the starting point is greater than a threshold value, the monitoring circuit triggers the control circuit to generate the second control code conversion table and to update the first control code conversion table in the storage device to the second control code conversion table.

12. The digital to analog conversion method of claim 9, wherein the monitoring circuit is an ADC.

13. The digital to analog conversion method of claim 9, wherein the DAC operates based on a bias current, and the control circuit further adjusts the bias current based on an SNR of the DAC.

14. The digital to analog conversion method of claim 13, wherein the bias current has a plurality of current levels, and the control circuit adjusts the bias current according to the SNR through following steps:
if the SNR is greater than an SNR threshold, continuing reducing the current level until the SNR being greater than the SNR threshold but closest to the SNR threshold, or less than the SNR threshold but closest to the SNR threshold;
if the SNR is less than the SNR threshold, continuing increasing the current level until the SNR being greater than the SNR threshold, or less than the SNR threshold but closest to the SNR threshold.

15. The digital to analog conversion method of claim 9, if the DAC receives the first N-bit control code, the DAC generates a second DAC output voltage different from the first DAC output voltage.

16. The digital to analog conversion method of claim 9, wherein the first control code conversion table and the second control code conversion table are generated by following steps:
inputting a plurality of N-bit control codes to the DAC to calculate an actual conversion curve;
obtaining 2^{Y} Y-bit control codes, and obtaining all candidate output voltages corresponding to the 2^{Y} Y-bit control codes through the actual conversion curve;
aligning a maximum one and a minimum one among the N-bit control codes to a maximum voltage and a minimum voltage that the DAC can output respectively;
allocating voltages between the maximum voltage and the minimum voltage to the N-bit control codes except the maximum N-bit control code and the minimum N-bit control code in an equal voltage difference manner, to obtain a plurality of required output voltages;
finding at least one output voltage among the candidate output voltages, wherein the output voltage is respectively closest to each one of the required output voltages, and establishing a conversion relationship of the control codes according to the output voltage.
